(19) United States
(12) Patent Application Publication
(10) Pub. No.: US 2007/0093061 A1
(43) Pub. Date: Apr. 26, 2007

(54) SOLVENT REMOVAL OF PHOTORESIST MASK AND GOLD IMPREGNATED RESIDUE AND PROCESS

(76) Inventor: John C. Moore, Camarillo, CA (US)

Correspondence Address: ARTHUR J. PLANTAMURA;GENERAL CHEMICAL PERFORMANCE PRODUCTS LLC., 90 EAST HALSEY ROAD, PARSIPPANY, NJ, 07054, US

(21) Appl. No.: 11/163,555

(22) Filed: Oct. 22, 2005

(51) Int. Cl. C09K 13/00; C23F 1/00; C03C 15/00; H01L 21/302

(52) U.S. Cl. 438/689; 252/79.1; 216/100; 216/90; 216/92

(57) ABSTRACT

Solvent removal of photoresist mask and gold containing post-etch residues in the production of semiconductor wafer plasma etching is effectively conducted prior to further processing of the wafer. Using metallic iodine dissolved in a polar solvent system, the chemistry penetrates and quickly dissolves the photoresist mask while iodine complexes and leaches away gold present in the etch residue to allow complete removal of all surface and residue polymer in one simple process. The system is in lieu of conventional procedures that require several process steps involving, first, the removal of the resist mask by an oxygen-rich plasma, otherwise referred to as “ashing,” followed by alternating inorganic and organic chemistries which react with gold and the post-etch polymer residue, and where the post-etch gold coated residue is heavy, requires repeated processing until the desired result is attained. The invention provides a simplified one-step process effected by immersion or a semiconductor wafer spray tool. Heat and agitation accelerate removal and help to achieve desired selectivity in removing the residue. Co-solvents and surfactants enhance penetration of small geometries and aid in rinsing.

This invention relates to a relatively simple and rapid system to remove all residues including photoresist masks and post etch residues and especially those that incorporate gold metal in the course of plasma etch fabrication steps on semiconductor wafers.

### BACKGROUND OF THE INVENTION

In gallium arsenide (GaAs) wafer processing, gold is commonly used for metal leads and contacts due to its superior electronic conductivity and resistance to corrosion. Metallic gold features may be sputter deposited from a plasma deposition system or electroplated from a chemical bath. When the wafer frontside features are completed, the wafer may then be coated with a dielectric of organic make-up (i.e., polyimide or bisbenzocyclobutene (BCB)), or sent directly to backside processing. For frontside organic dielectric coated (gallium arsenide (GaAs)) wafers, lithography and plasma etching steps may occur to establish via structures into the dielectric to expose metallic gold. Backside processing begins wafer thinning. After thinning, through-substrate vias are processed from the backside to the front, making contact to specific gold pad locations. These contact points are necessary to establish an electronic bias for the radio-frequency and/or semiconductor operations of the chip. In the course of the etch process, residue is produced that is composed of by-products of the photoresist mask incorporated into the plasma and also metallic gold that is sputtered away when contact is made to the gold etch-stop as further illustrated hereafter by reference to FIG. 1 of the drawing. The photoresist mask and the gold impregnated etch residue must be removed prior to further processing.

Removing gold impregnated post-etch residues in manufacturing semiconductor components heretofore has generally included a multiple-step chemical clean process. Post-etch residue is considered to be an amorphous mass of mixed polymer, wafer substrate (i.e., GaAs) and the metallic etch stop (i.e., gold). Metallic gold, the etch stop species in the device, is usually the last seen by the plasma. Gold that is etched from the substrate becomes redeposited on the surface of the residue. Conventional cleaning of the resist mask and etch residue usually begins with an ashing process using an oxygen plasma. The ashing process oxidizes the remaining resist mask and removes it from the substrate surface where it is evacuated as vaporized species. Ashing is followed by a post-etch residue removal phase involving first an acid in the presence of an iodide (e.g., potassium iodide) to initially remove the reverse sputtered (i.e., etched) gold from the sidewall of the via structure. Metallic gold is complexed with aqueous iodine and leached from the polymer network. This is followed by a de-ionized water rinse and dry, typically conducted in a spin-rinse-dry (SRD) tool. Once the gold is removed, the underlying cross-linked photoresist and substrate species (where applicable) are removed in a stripper step and sent again through the SRD as shown hereafter by reference to FIG. 2 of the drawing. In cases where deep, wide, or otherwise oversized via structures are made during etching, there may exist thick and tenacious residue which requires increasingly rigorous cleaning. This often includes repeating the process to alternate between the acidic-iodide bath (metallic gold removal), SRD, and into the organic solvent (polymer stripper) with a final SRD. Processes of this kind are cumbersome, time consuming, and expensive.

Industry consolidation has forced most GaAs substrate manufacturers to produce several device designs that use the same fab tooling, yet may have variable process times. Processes and materials are needed which also consolidate materials and steps to further streamline the flow of wafers through the fab. From the foregoing it is apparent that a chemical system which combines the removal of photoresist mask and gold metal residue into a single step rapid cleaning process would be highly advantageous.

### SUMMARY OF THE INVENTION

In accordance with the invention, we have discovered a blend of chemistries designed to simultaneously remove photoresist mask and post-etch polymer residues which have incorporated gold metal. The solvent system comprises a solvent soluble complexing agent specific for gold while the resist mask and polymer etch residue are simultaneously dissolved and rinsed away, thus significantly reducing process time and tool resources. Using metallic iodine dissolved in a polar solvent system, the iodine quickly complexes and leaches away metallic gold present in the etch residue while the solvent portion of the invention penetrates and quickly dissolves the photoresist mask and remaining surface polymer of the etch residue. This allows complete removal of the resist mask, impregnated gold, and post-etch deposited polymer to be removed in one simple process. Without this approach, the resist mask would have to be first removed in a separate process by either an oxygen-rich plasma, otherwise referred to as “ashing”, or by the use of a solvent. Additionally, the etch residue (not removed by ashing) must be dissolved away by chemical activity that commonly involves specialty chemistries or high pressure tooling which mechanically diffuse through or under the residue and lift it away. For etch processes which are ineffective in removing gold, the chemicals and post processing needed to produce a clean surface may become complicated to involve alternating inorganic and organic chemistries to first leach away the gold and then strip away the polymer residue with a solvent. In cases where the gold etch is heavy, the process generally has to be repeated until the desired result is attained. Heat and agitation may accelerate removal to achieve selectivity in removing a photoresist polymer that is present over another polymer such as an organic dielectric (e.g., polyimide or BCB). The composition of the invention contemplates inclusion of co-solvents and surfactants which enhance penetration of small geometries, disperse materials into the bulk media, and aid during the rinsing step, commonly using deionized water.

### BRIEF DESCRIPTION OF THE DRAWINGS

FIG. 1 is a flow diagram illustrating a typical GaAs substrate, lithography step, and the etching process that contributes to the gold impregnated etch residue and shows the materials present from the lithography step (photoresist mask) and plasma etching (polymer residue and metallic gold). The last element of the flow diagram indicates the condition of a plasma etched specimen containing both the remaining photoresist mask and post-etch residue with metallic gold.

FIG. 2 is a flow diagram illustrating conventional cleaning of a GaAs substrate using separate polymer stripping and gold removal. Shown are both remaining photoresist mask and post-etch residue with metallic gold and a structure resulting from a plasma etch process. The steps in typical cleaning processes include the photoresist mask removal using oxygen-rich plasma ashing, metallic gold dissolving and removal, spin-rinse drying (SRD), solvent stripping of residual polymer post-etch residue, and a final SRD. FIG. 2 illustrates also the sequence for repeating the process where the presence of excessive residue may warrant re-insertion of the specimens back into the clean process.

FIG. 3 is a flow diagram illustrating the cleaning process of the invention utilizing a GaAs substrate containing both remaining photoresist mask and post-etch residue with metallic gold following the processing via structure plasma etch. In the process flow, only a single step is required for complete resist mask removal, gold dissolving, and post-etch residue removal, followed by a spin-rinse drying (SRD) step.

FIG. 4 is a bar graph illustrating metallic gold etch (removal) rates in Å/min of test specimens containing plasma sputtered metallic gold that have been exposed to different solvents including dimethyl acetamide (DMAC), dimethyl sulfoxide (DMSO), and gamma-butyrolactone (GBL), containing 0.1% (w/w) of metallic iodine, wherein measurements were conducted using a profilometer and consistent with standard methods used for semiconductor wafers. The gold being measured by profilometry against known thickness of 1 μm=10,000 Å, the rates being measured at 65° C. for 15 minutes.

FIG. 5 is a graph illustrating metallic gold etch (removal) rates in dimethyl acetamide (DMAC) containing variable contents of metallic iodine. The gold being measured by profilometry against known thickness of 1 μm=10,000 Å, the rates being measured at 65° C. for 15 minutes.

FIG. 6 is a graph illustrating metallic gold etch (removal) rates over time as measured in a spray tool with metallic Iodine content of 0.3% (w/w) in DMAC, and performed at 65° C. and with the metallic gold being measured by profilometry against known thickness of 1 μm=10,000 Å.

FIGS. 7 (a) and (b) show Scanning Electron Microscopy (SEM) scan photos of frontside BCB dielectric coated GaAs substrate with via structures etched to a plasma sputtered metallic gold layer and showing gold impregnated residue present on sidewalls of etched via structure (a) and cleaned via structure (b).

FIGS. 8 (a) and (b) show Scanning Electron Microscopy (SEM) scan photos of frontside BCB dielectric coated GaAs substrate showing structures etched to an electrochemical deposition (ECD) metallic gold layer. The SEM photos showing gold impregnated residue present on sidewalls of the etched structure (a) and cleaned structure (b) which shows complete removal of post-etch residue with metallic gold, the artifacts present on the etched surface do not detract from the gold removal/cleaning process.

FIGS. 9 (a) and (b) show Scanning Electron Microscopy (SEM) scan photos of a 75 μm backside via structure on GaAs substrate with etch stop onto metallic gold layer and show gold impregnated at bottom of etched structure (a) and the cleaned structure (b) with cleaning performed in a single wafer spray cleaning tool, 65° C., <5 minutes, using invention chemistry containing DMAC as main solvent system and 0.3% (w/w) of metallic iodine.

### DETAILED DESCRIPTION OF THE INVENTION

According to the invention, metallic iodine dissolved in a polar solvent system complexes and leaches away gold present in the etch residue while the polar solvent penetrates and quickly dissolves the photoresist mask and post-etch polymer residue to allow complete removal of unwanted residue in a single combined chemical application. Typical of lithography operations, the photoresist mask (polymer patterned region) and any residue following an etch process must be removed prior to subsequent processing steps. The mask areas to be removed commonly require separate removal processes and tooling. For the resist mask, the polymer is either ashed away by an oxygen plasma, typically done by a dedicated tool. The etch residue must be dissolved away by chemical activity that may involve specialty chemistries or high pressure systems which mechanically diffuse through or under the residue and lift it away. For etch processes which are interrupted upon encountering gold, the chemicals and post processing needed to produce a clean surface are frequently complicated and involve additional chemistries to first leach away the gold followed by a solvent to strip away the polymer residue and where the gold etch is heavy, the process often needs to be repeated until the desired result is attained.

In accordance with the novel system of the invention, a formulated product comprising approximately 50-90 parts by weight of a polar solvent such as dimethylacetamide (DMAC), 5-20 parts by weight of a co-solvent, effective amounts of, i.e., about 0.05% to about 5.0% and preferably 0.1% to about 0.5% by weight of metallic iodine as a gold complexing agent (i.e., iodine, I₂, at. wt.=126.9, metallic, as plates or beads), and 0.01-2 parts by weight of a surfactant. Typical polar solvents include DMAC, dimethylsulfoxide (DMSO), gamma-butyrolactone (GBL), or such solvent exhibiting a relatively high dielectric constant or other polarity factor, such that its physical chemistry parameters will effect solvency of the metallic iodine, yet maintain good penetration, swelling, and dissolving of the photoresist mask and post-etch polymer residue. Examples of certain values which may be used to measure polarity of liquids include dielectric constant which for preferred polar solvents such as DMAC, DMSO, and GBL, indicate values of approximately 38, 46, and 39, respectively, as compared to low dielectric constant solvents such as hexane which exhibits a value of <2, as printed in the Handbook of Chemistry and Physics, CRC Press, Inc., Boca Raton, Fla., 67 ed., or later. The high polarity liquids contemplated as useful in accordance with the invention is based upon their relatively high dielectric constant values, which should be at least 30 and the high solvency character towards polymer systems representative of the particular task, i.e., the nature of the photoresist.

Performance tests for removing metallic gold were performed in different solvents. Dissolution of metallic iodine occurs easily in the solvents DMAC, DMSO, and GBL. Following the dissolution of iodine at a concentration of 0.1%, etching (removal) tests were performed on sputtered metallic gold of a known thickness. Metallic gold thickness was measured with a profilometer using a stylus-based monitor of the type as produced by KLA-Tencor, commonly used for thin film measurement on semiconductor wafers. Immersion tests were carried-out for 15 minutes, rinsed in deionized water, and oven dried. Tests were repeated five (5) times with separate test specimens, each measured with the profilometer against a known thickness of 1 micron (μm)=10,000 Å of plasma sputtered metallic gold. Values are entered into a mathematical algorithm which corrects for removal, time, and considers a 90% confidence level for the number of tests performed. Results measured are for DMAC, DMSO, and GBL noted as 28, 178, and 51 Å/min, as the etch (dissolution) rate for metallic gold. These results are shown in FIG. 4.

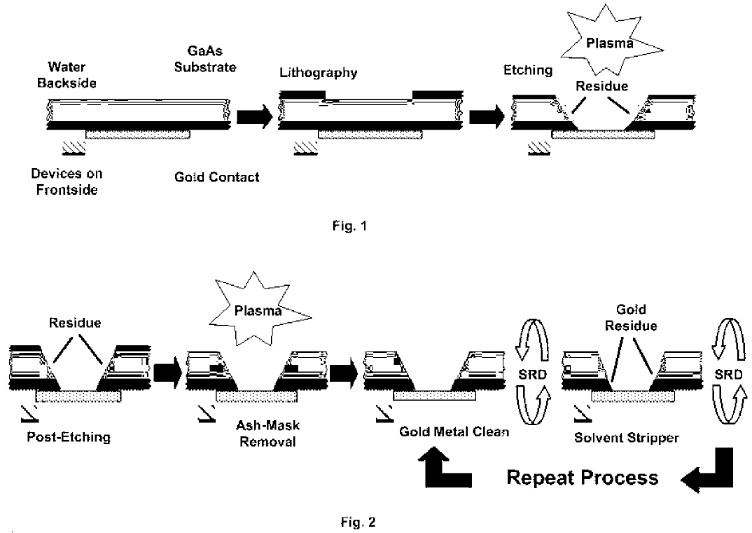

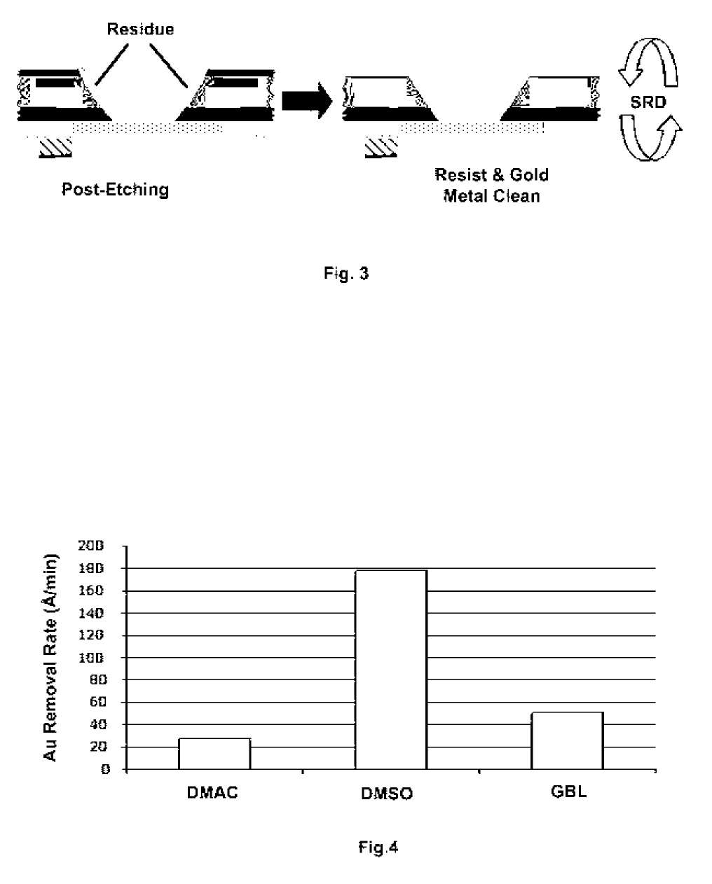

Continued work occurred on similar substrate specimens to determine preferred rate of resist removal and compared to that with metallic gold removal. The primary goal of this development is to achieve maximum photoresist stripping with minimum metallic gold removal. As illustrated by FIGS. 1-3, it is important that the gold impregnated post-etch residue exposed to the process chemistries, as well as the gold layer at the bottom of the structure be taken into account. Etching that is too aggressive will result in a thinner gold layer and possible undercutting at the interface of the gold layer and semiconductor substrate (i.e., GaAs). Based upon a review of designs typical of the device shown in FIG. 1, a maximum metallic gold removal of 1000 Å is acceptable for the entire cleaning process. Therefore, for the etch rates seen for DMAC, DMSO, and GBL, as indicated in FIG. 4, maximum process times for each to remove near 1000 Å at near 65° C. would be approximately 35, 5, or 15 minutes, respectively when rounded down by 5 minute increments. Considering the high polymer solvency rate for DMAC, further work was demonstrated in the solvent DMAC.

Performing metallic gold removal with varying iodine concentrations in DMAC fluids indicated rates of 19, 28, and 57 Å/min for 0.05, 0.1, and 0.3% (w/w), respectively. The rates being measured in these solutions at 65° C. for 15 minutes. This information in the form of metallic gold removal against iodine is shown in FIG. 5. Performing the same calculations for process time and a maximum of 1000 Å removal, suggests a maximum time of 50, 35, or 15 minutes, for iodine concentrations of 0.05, 0.1, and 0.3% (w/w), respectively. Considering an amount of 0.3% iodine content in DMAC, a five (5) minute process time, normally used as a guideline for general cleaning work, would be within a 2-fold buffer from the maximum limit of metallic gold removal.

Co-solvent additives that may be used include such as a propylene-based glycol ether (e.g., tripropylene glycol monomethyl ether) and a hydrocarbon-based surfactant used to penetrate small geometries and aid in rinsing. Suitable surfactants include non-ionic alkoxylated linear alcohols such as the tradename Polytergent SL92, available from BASF Corporation. The surfactant functions to reduce surface tension and aid in the rinsing process. The surfactant preferably has a high cloud point (i.e., >60° C.) to allow for heated processing and rinsing without miscibility issues. Surfactants providing a non-ionic environment are required for inert conditions towards dissolved metals and maximum solubility in a wide range of media, both solvent and water. Surfactants with low foaming capacity allow for product use in various automated equipment. Examples of suitable alternative surfactants include nonyl-phenols and nonyl-ethoxylates with a HLB (hydrophilic/lipophilic balance) ranging from 7-15. Less than about 2 weight percent of the non-ionic surfactant and preferable an amount of about 0.01 to about 0.4 weight percent is sufficient.

The compositions of the invention have significantly low viscosity. Combining this physical property with the presence of a surfactant allows the wetting of surfaces by contact angle reduction, penetration, and a high rate of diffusion. These physical-chemical properties synergistically combine to enable superior performance beyond that exhibited individually. Tenacious organic material from the resist mask or post-etch process is penetrated, dissolved, emulsified, and suspended to prevent-redeposition, allowing easy rinsing. The low foaming characteristic of the invention allows greater efficiency for capillary action to microscopic dimensions during a variety of agitation conditions. Use of heat and agitation in using the photoresist removal composition of the invention leads to improve performance.

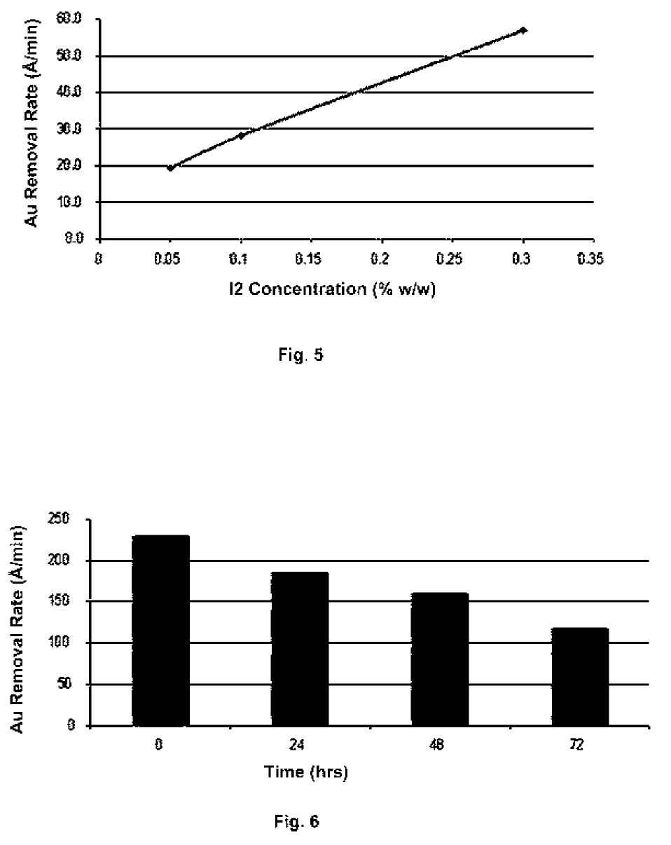

The composition of the invention is intended for use at a range of temperatures. It may be sprayed, or used in an immersion-based cleaning system. Agitation is not necessary, but will significantly enhance performance. A variety of agitation forms may be used, including mixing, spraying, and ultrasonic agitation at a variety of frequencies, typically ≦170 kHz. In one condition, metallic gold etch (removal) rates were measured over time in a single wafer tool, similar to that manufactured by Semitool, a Capsule module where the wafer is held in place by a clam-shell type system in a face-down condition with spray nozzles pointing upward directly at the wafer surface to be cleaned while the wafer is rotating at a given rpm. Due to the high agitation rates in this tool as compared with immersion, the metallic gold removal was noted to be approximately 4-fold greater at the same conditions of 65° C. using the DMAC chemistry with 0.3% (w/w) metallic iodine. This rate was observed to decrease over time at values of 230, 185, 160, and 118 Å/min for times at T=0, 24, 48, and 72 hrs, respectively, for approximately 500 6″ wafers per day. These values are by reference to FIG. 6.

The composition of the invention is preferably used at full strength because dilution tends to reduce effectiveness and may completely render it ineffective. It is preferred that the composition be used at warm conditions, just above room temperature and with the minimum amount of heat needed to achieve the desired results. Although heat will enhance the cleaning power, excess heat may accelerate metallic gold etching at locations undesirable, therefore reducing the iodine content over time and deteriorate overall performance. Deionized water is preferred to rinse the product. Alternative and compatible solvents such as alcohol (IPA) or acetone may be used in conditions where water may not be acceptable.

The feasibility of the solvent system of the invention in removing relatively difficult gold bearing photoresist residues, have been demonstrated in both an immersion and single wafer spray. The invention will be more fully understood by the illustrative procedure and examples which follow, however, the invention is not to be limited to the specific details described except to the extent required by the appended claims.

General Procedure

Preparation of the chemistry of the invention preferably comprising DMAC as the main solvent and with metallic iodine and supplementary additives is conducted in sequence with all such ingredients added, except for the metallic iodine. The total of the main solvent, e.g., DMAC, initially admixed is 95% (w/w or v/v) of the calculated total with the remaining 5% (w/w or v/v) used for preparing a concentrated metallic iodine mixture. The metallic iodine solubility in DMAC is in excess of 20% (w/w), therefore, using the 5% concentrate approach for a 0.3% (w/w) level would produce a 6% (w/w) concentration which is well within the solubility range of 20%. Once the 95% solvent mix is completed (e.g., DMAC 95%+co-solvent+surfactant), the metallic iodine remaining 5% DMAC concentrate may be added. Full solubility and mixing occurs and the material may then be packaged and retained for use. Shelf life of the product as packaged in compatible plastic bottles is deemed to be in excess of 6 months when stored at cool and dark conditions, away from incompatible chemicals.

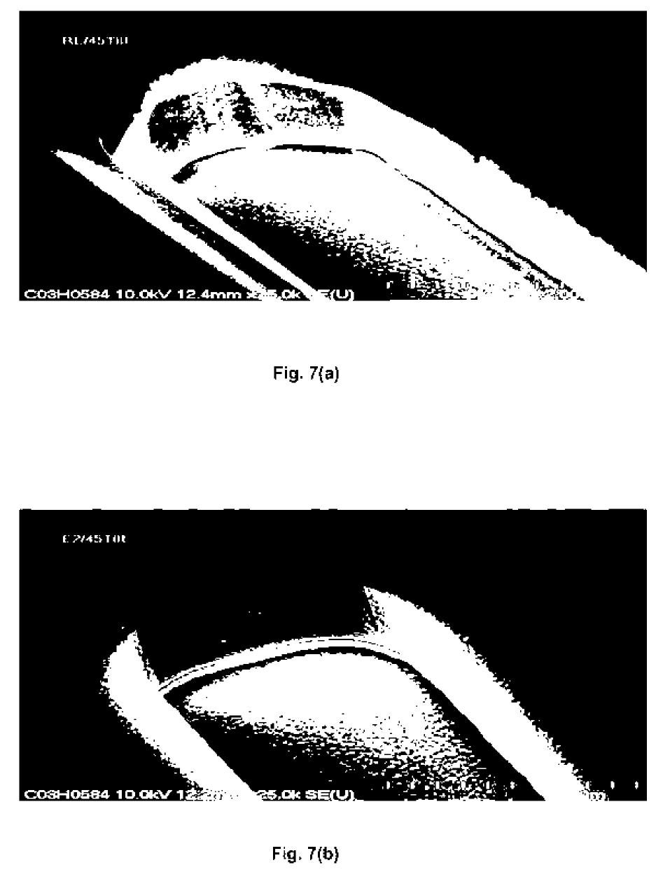

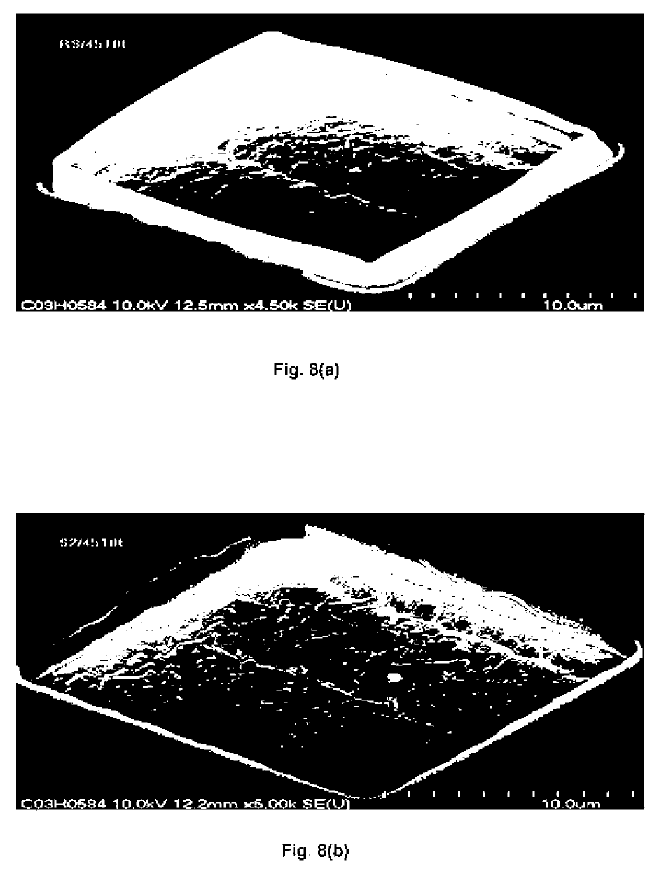

Demonstrations were performed using the invention in a standard immersion condition. Non-thinned 100 mm (4″) wafers with frontside via structures etched into BCB. Via structures vary in size between 35-90 μm in diameter. BCB etching condition used a CF₄/O₂ gas mixture in the plasma with etch stop onto both sputtered and electrochemical deposited (ECD) metallic gold. Results of a 5 minute immersion clean at 65° C. followed by a deionized water rinse are shown by FIGS. 7 (sputtered gold) and 8 (ECD gold), with scanning electron microscopy (SEM) pictures (before and after) showing resist mask around the via structure and post-etch residue with impregnated metallic gold. The after-photo indicates complete removal of the resist mask and etch residue.

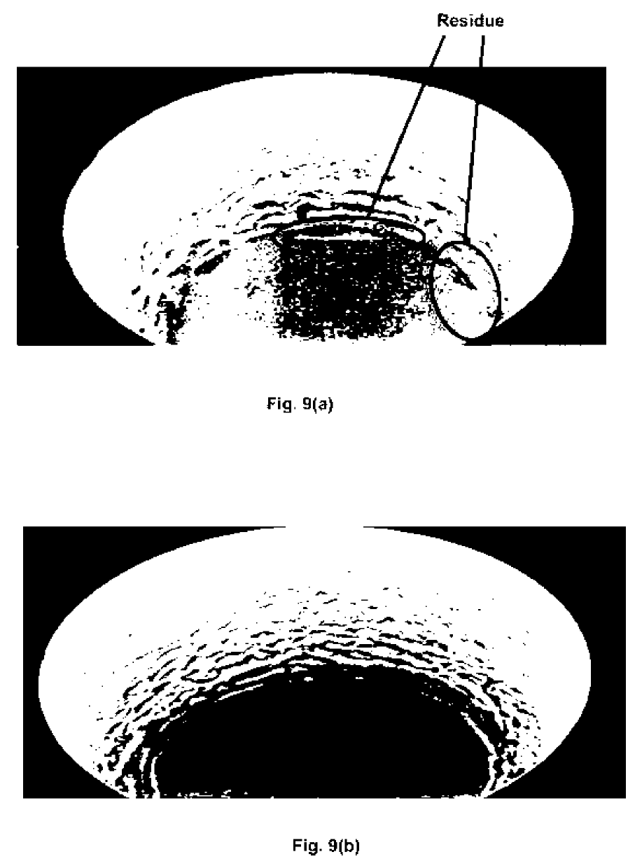

In another example, thinned (i.e., approximately 90 μm thick) 150 mm (6″) wafers bonded to sapphire carriers indicating backside via structures etched into the GaAs substrate. Via structures are approximately 50 μm in diameter were used. GaAs etching condition used a BCl₃/Cl₂ gas mixture in the plasma with etch stop onto metallic gold. Results of a <5 minute spray tool clean at 65° C. followed by a deionized water rinse are shown in FIG. 9, which shows scanning electron microscopy (SEM) pictures before at (a) and after at (b) of post-etch residue with impregnated metallic gold at the bottom of the via. The after-photo (b) indicates complete removal of the etch residue.

Although the invention has been described in terms of specific embodiments, one skilled in the art within the purview of the invention can substitute embodiments and these are meant to be included herein. The invention is only to be limited by the scope of the appended claims.

What is claimed is:

1. A stripping composition for removing polymeric organic substances and organic residues containing metallic gold within the matrix from inorganic substrates and substrates containing an exposed organic dielectric layer in the manufacture of semiconductor elements, comprising from about 50 to about 95 percent by weight of a polar solvent having a dielectric constant of greater than 30 and metallic iodine from about 0.05 to about 5 percent by weight.

2. The composition of claim 1 wherein the polar solvent is dimethylacetamide and contains a co-solvent and a surfactant.

3. The composition of claim 2 which includes tripropyleneglycol monomethyl ether (TPM) cosolvent in amounts of from about 5 to 20 percent by weight.

4. The composition of claim 3 containing a nonionic surfactant having a concentration of 0.01 to 2 percent by weight.

5. The composition of claim 1 wherein the polar solvent is dimethylsulfoxide.

6. The composition of claim 1 wherein the polar solvent is gamma-butyrolactone.

7. A method for stripping gold bearing polymeric layers from an inorganic substrate by applying to said substrate the composition of claim 4 and wherein the etch (removal) rate for metallic gold varies from 19 to 57 angstroms per minute (Å/min), depending upon metallic iodine content and for a process period of time not to exceed 15 minutes.

8. The method of claim 7 in which stripping a gold bearing polymeric layer from an inorganic substrate, the improvement characterized in that the substrate is stripped for a period of time sufficient to strip the gold bearing layer from the substrate.

9. In a method for stripping polymeric organic substances and organic residues containing metallic gold within the matrix from an inorganic substrate, the improvement characterized in that the substrate is stripped in a single application with the composition of claim 1 for a period of time sufficient to remove the organic substance.

10. The method of claim 8 in which the organic substance to be stripped from the inorganic substrate is performed by immersion and spray tool application for a period of time <5 minutes and at 65° C., followed by a deionized water rinsing.
